(19) United States
(12) Patent Application Publication
(10) Pub. No.: US 2006/0154464 A1
(43) Pub. Date: Jul. 13, 2006

(54) Semiconductor device and a method of fabricating a semiconductor device

(75) Inventor: Kazuyuki Higashi, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/218,722

(22) Filed: Sep. 6, 2005

(30) Foreign Application Priority Data
Jan. 7, 2005 (JP) P2005-2637

(51) Int. Cl. H01L 21/44; H01L 23/48

(52) U.S. Cl. 438/597; 438/656; 257/763

(57) ABSTRACT

A semiconductor device includes a semiconductor substrate; a porous low k dielectric disposed on the semiconductor substrate having a plurality of trenches therein, the porous low k dielectric having an effective dielectric constant of 3.0 or less; a plurality of barrier layers provided on each surface of the trenches, each of the barrier layers including a plurality of films having different film densities; a plurality of metal diffused regions provided in the porous low k dielectric and contacting the barrier layers; and a first conductor embedded in one of the trenches in contact with one of the barrier layer.

### CROSS REFERENCE TO RELATED APPLICATIONS AND

### INCORPORATION BY REFERENCE

This application is based upon and claims the benefit of priority from the prior Japanese Patent Applications No. P2005-002637, filed on Jan. 7, 2005; the entire contents of which are incorporated herein by reference.

### BACKGROUND OF THE INVENTION

1. Field of the Invention

The present invention relates to a semiconductor device, more specifically to a semiconductor device including a porous low k dielectric material as an interlayer dielectric.

2. Description of the Related Art Along with the miniaturization of semiconductor devices, transmission delays and signal interruption by crosstalk between wiring have become a subject for closer examination. Copper (Cu), which has a lower resistivity than aluminum (Al), has been adopted as conductive materials and a method for suppressing resistance by 30% has been employed. A low-k dielectric having a lower dielectric constant than a silicon oxide film (SiO₂) has been adopted as an interlayer dielectric and a method of reducing capacitance between the wiring has also been examined. Recently, the practical use of a porous low k dielectric (porous-low-k film) having microscopic pores in a dielectric has been tried.

In a recent copper damascene process, it is known that a copper barrier layer (barrier) is deposited on a surface of a trench in a dielectric by utilizing physical vapor deposition (PVD) such as sputtering. Then, a Cu nucleation layer may be deposited on the barrier by plating, or the like.

However, the miniaturization of integrated circuits makes it difficult to deposit conformal layers on a sidewall of the trench by sputtering. Therefore, atomic layer deposition (ALD) and chemical vapor deposition (CVD), characterized by excellent conformality and thickness control, are still receiving attention for depositions of conductors and barriers.

However, since the porous low k dielectric includes many pores in the dielectric, density is relatively low and is easily affected by atmospheric conditions. When barriers are deposited on the porous low k dielectric by CVD or ALD, process gases and metallic atoms may go into the pores in the porous low k dielectric. Consequently, leakage of the wiring and an increase in wiring capacitance may occur.

To prevent adsorption of process gasses into the layer of the porous low k dielectric material, a method of providing chemical treatments to the surface of the porous low k dielectric before depositing barriers there on by CVD or ALD has been proposed. However, since the barriers deposited by CVD or ALD have poor adhesion strength, the barriers may peel off after fabrication.

### SUMMARY OF THE INVENTION

An aspect of the present invention inheres in a semiconductor device encompassing a semiconductor substrate; a porous low k dielectric disposed on the semiconductor substrate having a plurality of trenches therein, the porous low k dielectric having an effective dielectric constant of 3.0 or less; a plurality of barrier layers provided on each surface of the trenches, each of the barrier layers including a plurality of films having different film densities; a plurality of metal diffused regions provided in the porous low k dielectric and contacting the barrier layers; and a first conductor embedded in one of the trenches in contact with one of the barrier layer.

Another aspect of the present invention inheres in a method of fabricating a semiconductor device encompassing forming a porous low k dielectric having an effective dielectric constant of 3.0 or less on a semiconductor substrate; providing a plurality of trenches in the porous low k dielectric; providing a plurality of barrier layers, each one of the barrier layers including a plurality of films having different film densities on surfaces of corresponding one of the trenches; forming a plurality of metal diffused regions in the porous low k dielectric and in contact with the barrier layers; and embedding first and second conductors in the trenches in contact with the barrier layer, the second conductor is embedded in one of the trenches adjoining the trench in which the first conductor is embedded.

### BRIEF DESCRIPTION OF DRAWINGS

FIG. 1A is a cross-sectional view illustrating a semiconductor device according to a first embodiment of the present invention.

FIG. 1B is an enlarged view in a dotted line region illustrated in FIG. 1A.

FIGS. 2 to 6 are cross-sectional views illustrating a method of fabricating the semiconductor device according to the first embodiment of the present invention.

FIG. 7 is a cross-sectional view illustrating a semiconductor device according to a second embodiment of the present invention.

FIGS. 8 and 9 are cross-sectional views illustrating a method of fabricating the semiconductor device according to the second embodiment of the present invention.

FIGS. 10 and 11 are cross-sectional views illustrating semiconductor devices according to other embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified. However, it will be obvious to those skilled in the art that the present invention may be practiced without such specific details.

### FIRST EMBODIMENT

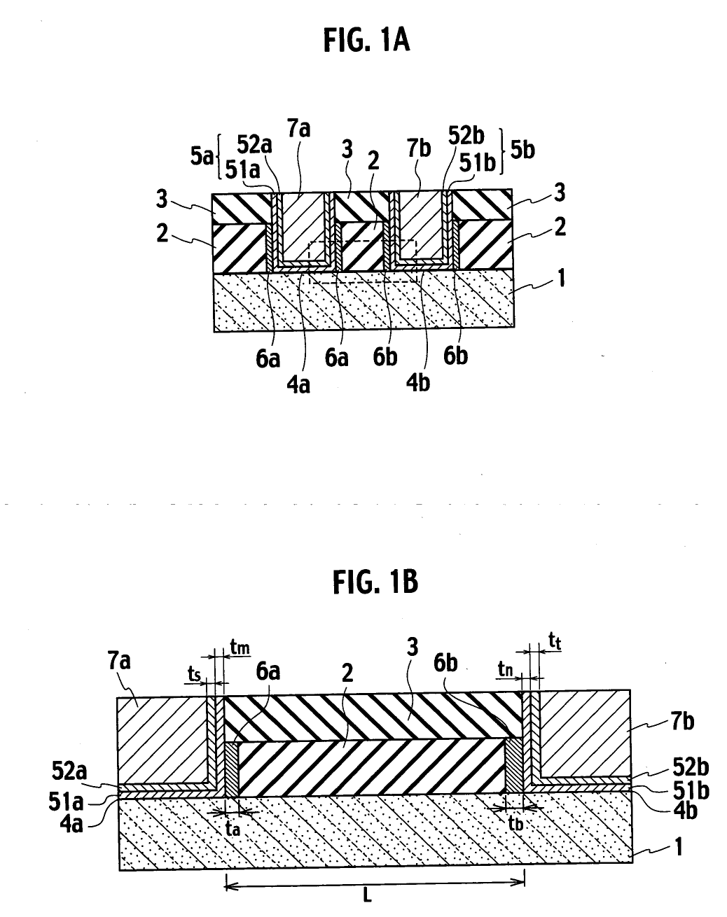

As shown in FIG. 1, a semiconductor device according to the first embodiment of the present invention includes a semiconductor substrate 1, a porous low k dielectric 2 having trenches 4a, 4b and disposed on the semiconductor substrate 1, barrier layers 5a, 5b provided on a surface of the trenches 4a, 4b, metal diffused regions 6a, 6b provided in the porous low k dielectric 2 and in contact with the barrier layers 5a, 5b, and first conductors 7a, 7b embedded in the trenches 4a, 4b in contact with the barrier layers 5a, 5b.

A stopper film 3, which is made from insulative material, may be disposed on the porous low k dielectric 2. A part of the barrier layers 5a, 5b and the conductor 7a, 7b may be formed in the stopper film 3.

In FIG. 1A, a semiconductor device fabricated by damascene processes is illustrated as an example of a semiconductor device according to the first embodiment. In FIG. 1A, transistors, isolation regions located adjacent to the semiconductor substrate 1 and other interconnects provided above the stopper film 3 are omitted.

As to the porous low k dielectric 2, a film having microscopic pores in the film and having an effective dielectric constant of 3.0 or less may be utilized. Various materials can be used as the porous low k dielectric 2. For example, a film having a porosity of 10% and above, more suitably in a range of from about 10% to about 35%, can be used as the porous low k dielectric 2. A film having an effective dielectric constant in a range of from about 1.5 to about 3.0 , more suitably in a range of from about 2.0 to about 2.5 can be used as the porous low k dielectric 2.

Porous low k dielectric 2, materials having the effective dielectric constant of 3.9 or less may be used by lowering film density of the SiO₂ film. Such materials as a methyl silsesquioxane (MSQ:CH₃SiO_{1.5}), a hydrogen silsesquioxane (HSQ:H-SiO_{1.5}) , aporous MSQ, a porous HSQ, and organic silica (CH₃-SiOₓ) can be used. Organic films having lower polarizability such as a polytetrafluoroethelene (PTFE), a polyarylether (PAE) , a porous PAE, and a benzocycrobthene (BCB) can be used as the dielectric film.

The barrier layers 5a, 5b are composed of a plurality of films having different film densities with respect to each other. Referring to FIG. 1A, the barrier layers 5a, 5b include first barrier films 51a, 51b are provided on the surface of the trenches 4a, 4b, respectively, and second barrier films 52a, 52b are provided on surfaces of the first barrier films 51a, 51b , respectively.

The first barrier films 51a, 51b are films with surface asperity. As shown in FIG. 1B, which is an enlarged view of the dotted line region in FIG. 1A, a film thickness tm of the first barrier film 51a in contact with the sidewall of the trench 4a may be in a range of from about 1 nm to about 3 nm. A film thickness tₙ of the first barrier film 51b in contact with the sidewall of the trench 4b may be in a range of from about 1 nm to about 3 nm. The first barrier films 51a, 51b can be made from titanium (Ti), niobium (Nb) , tantalum (Ta) , rubidium (Ru) , tungsten (W) , and compounds such as alloys, nitrides, oxides, and carbides, which are made from at least two materials selected from above described materials.

The second barrier films 52a, 52b are more closely dense film than the first barrier films 51a, 51b . A film thickness tₛ of the second barrier film 52a in contact with a sidewall of the first barrier film 51a may be in a range of from about 1 nm to about 10 nm. A film thicknesstₜ of the second barrier film 52b in contact with a sidewall of the first barrier film 51b may be in a range of from about 1 nm to about 10 nm. The second barrier films 51a, 51b can be made from Ti, Ta, Ru, W, Al, and compounds such as alloys, nitrides, oxides, and carbides, which are made from at least two materials selected from above described materials.

The metal diffused regions 6a, 6b are conductive regions formed by diffusing process gasses including metallic atoms into the porous low k dielectric 2 while depositing the barrier layers 5a, 5b. The metallic atoms are retained in the pores in the metal diffused regions 6a, 6b . The metal diffused region 6a is provided in the porous low k dielectric 2 and in contact alongside of the first barrier film 51a . The metal diffused region 6b is provided in the porous low k dielectric 2 and in contact alongside of the first barrier film 51b.

A thickness tₐ, t_{b} of the metal diffused regions 6a, 6b in contact with the first barrier films 51a, 51b and the porous low k dielectric 2 may be 1/20 or less of a minimum distance (minimum space width) L between the first conductor 7a and the second conductor 7b . Thickness tₐ, t_{b} of the metal diffused regions 6a, 6b may be varied by technology generations of the semiconductor devices. In FIG. 1B, thickness tₐ, t_{b} of the metal diffused regions 6a, 6b may be in a range of from about 1 nm to about 3 nm.

The conductors 7a, 7b may be interconnects or contact plugs connected to impurity regions (not shown) formed in the semiconductor substrate 1. The conductors 7a, 7b may be filled at a location where interconnects and contact plugs are integrated with each other. As to the conductors 7a, 7b , materials such as Al, Al-Cu alloy, Cu, and the like, can be used. The stopper film 3 may include a plurality of films. The stopper film 3 may be made from insulative materials such as a silicon carbide (SiC) , a silicon carbide nitride (SiCN), a silicon nitride (SiN), a carbon doped silicon mono oxide (SIOC) , SiO₂, and the like.

With the semiconductor device according to the first embodiment, metal diffused regions 6a, 6b are provided in the porous low k dielectric 2 and in contact with the barrier layers 5a, 5b. The metal diffused regions 6a, 6b serve as a “barrier wall” to prevent diffusion of.moisture and process gases into the pores in the porous low k dielectric 2. Therefore, diffusion of metals, moistures, and other gasses into the porous low k dielectric 2 are suppressed. Consequently, leakage of conductive materials into the porous low k dielectric 2 and a capacitance increase may be prevented.

Moreover, since the metal diffused regions 6a, 6b are provided between the porous low k dielectric 2 and the barrier layers 5a, 5b, adhesion strength between the porous low k dielectric 2 and the barrier layers 5a, 5b will be improved. Therefore, breakage between the porous low k dielectric 2 and the barrier layers 5a, 5b can be suppressed, and semiconductor devices with a higher fabrication yield may be achieved.

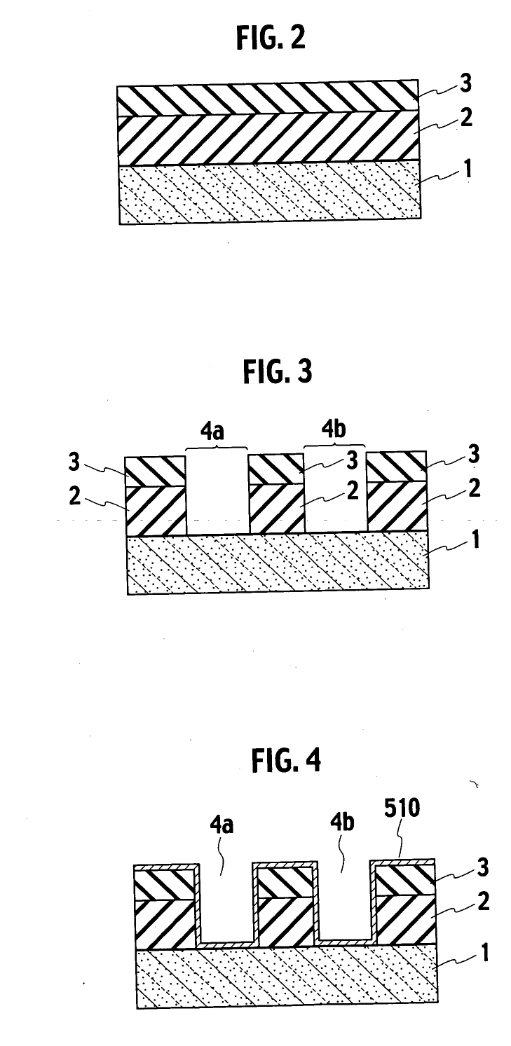

Next, a description will be given of a method of fabricating the semiconductor device according to the first embodiment with reference to FIGS. 2 to 6. The method of fabricating the semiconductor device described below is an example, and it is obvious that various fabricating methods can be implemented.

Referring to FIG. 2, the porous low k dielectric 2 is formed by CVD, or the like on the semiconductor substrate 1. The porous low k dielectric 2 may have a porosity of 10% or more, suitably, in a range of from about 10% to about 35%. The porous low k dielectric 2 may have an effective dielectric constant of from about 1.5 to about 3.0 , more suitably, in a range of from about 2.0 to about 2.5 . A stopper film 3 such as SiO₂ is formed on the porous low k dielectric 2 by CVD, or the like. A photoresist film (not shown) is spin-coated on the surface of the stopper film 3. Then, the photoresist film is delineated by use of a photolithography process. A part of the stopper film 3 is selectively stripped by reactive ion etching (RIE) by use of the delineated photoresist film as an etching mask. Thus, as shown in FIG. 3, the trenches 4a, 4b penetrating the porous low k dielectric 2 and the stopper film 3 are formed.

Referring to FIG. 4, a first barrier 510 having surface asperities is formed on the porous low k dielectric 2, the stopper film 3, and the trenches 4a, 4b, respectively. A. film thickness of the first barrier 510 in contact with the sidewall of the trenches 4a, 4b may be controlled within a range of from about 1 nm to about 3 nm. For example, the temperature may be set at 300° C. or less, and the first barrier 510, which is made from Ti, Nb, Ta, Ru, W, and compounds such as alloys, nitrides, oxides, and carbides made from at least two materials selected from above materials, may be deposited by sputtering.

Referring to FIG.5, a second barrier 520 having a film density higher than the first barrier 510 is formed on the first barrier 510. A film thickness of the second barrier 520 in contact with the sidewall of the first barrier 510 may be controlled within a range of from about 1 nm to about 10 nm. For example, the temperature may be set at 400° C. or less, and compounds such as alloys, nitrides, oxides, and carbides, which are made from at least two materials selected from Ti, Nb, Rh, Ta, W, and Al may be deposited by CVD or ALD or the like. While depositing the second barrier 520 on the first barrier 510, process gases may go into the porous low k dielectric 2 through the first barrier 510. Accordingly, metal diffused regions 6a, 6b are formed in the porous low k dielectric 2.

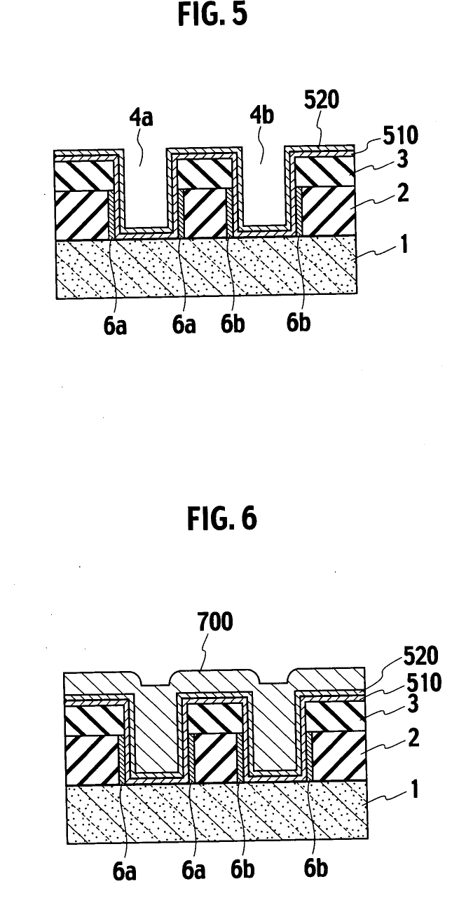

Referring to FIG. 6, a conductive layer 700 is deposited on a surface of the second barrier 520 by plating, or the like. The conductive layer 700 is polished by CMP until the surface or the stopper film 3 is exposed, thus the semiconductor device as shown in FIG. 1 is formed.

With the method of fabricating the semiconductor device according to the first embodiment, the first barrier films 51a, 51b are formed by sputtering before the second barrier films 52a, 52b are formed by CVD or ALD. The first barrier films 51a, 51b deposited by sputtering have a microscopic asperity on surfaces thereof. Therefore, a wetting characteristic between the first barrier films 51a, 51b and the second barrier films 52a, 52b will be improved, and breakage between the films will be prevented.

Moreover, since the first barrier films 51a, 51b , which have a lower film density, may be deposited before the second barrier films 52a, 52b , which have a higher film density, are deposited, diffusion of the metallic atoms and process gases occurring in deposition of the second barrier films 52a, 52b may be prevented at a predetermined level by the first barrier films 51a, 51b . Therefore, the thickness of the metal diffused regions 6a, 6b , which serve to prevent further diffusion of gases and metallic atoms into the porous low k dielectric 2, may be controlled to a desired level. Consequently, an increase in capacitance of interconnects may be suppressed.

For example, referring to FIGS. 2 to 6, the thickness tₘ, tₙ of the first barrier films 51a, 51b is controlled within a range of from about 1 nm to about 3 nm and thickness tₛ, tₜ of the second barrier films 52a, 52b , is controlled within a range of from about 1 nm to about 10 nm. Therefore, the thickness of metal diffused regions 6a, 6b can be controlled to 1/20 or less of the minimum space width between the conductors 7a, 7b.

The reason that the film thickness tₘ, tₙ of the first barrier films 51a, 51b is controlled to from about 1 nm or more is because when the first barrier films 51a, 51b are deposited with a thickness of about 1 nm by sputtering, the metallic atoms can be deposited to approximately ten atomic layers. Accordingly, a desirable amount of the process gases may go into the porous low k dielectric through void spaces formed in the atomic layers. Whereas, the reason that the film thickness tₘ, tₙ of the first barrier films 51a, 51b is controlled to about 3 nm or less is because when the metallic atomic layers are deposited at a thickness of over 3 nm, the first barrier films 51a, 51b become too dense and void spaces in the metallic atomic layers become smaller. Accordingly, it becomes difficult to diffuse the desired amount of gasses to the porous low k dielectric 2.

When the thickness of the metal diffused regions 6a, 6b , is controlled to 1/20 or less of the minimum space width between the conductors 7a, 7b , problems such as leakage between adjoining wirings, an increase in capacitance caused by diffusing conductive materials into the dielectrics can be prevented. Consequently, a semiconductor device having high reliability can be fabricated.

The porous low k dielectric 2 having an effective dielectric constant of 2.2 and a porosity of 30% can be prepared in accordance. The trenches 4a, 4b are formed in the porous low k dielectric 2 after the dielectric has been deposited on the substrate. A minimum distance between the trenches 4a, 4b (conductors 7a, 7b ) is set to about 70 nm. Then, the first barrier films 51a, 51b are deposited by sputtering by use of Ti at a room temperature. The film thickness of the sidewalls of first barrier films 51a, 51b is formed to be approximately 1 nm. The film thickness of the bottoms of the first barrier films 51a, 51b is formed to be approximately 3 nm. After that, the second barrier films 52a, 52b are deposited by ALD by use of TaN at a temperature of at 250° C. Consequently, the metal diffused regions 6a and 6b having a total thickness of approximately 6.9 nm, which is 1/10 less than the minimum space width between conductors 7a and 7b (70 nm), can be fabricated.

### SECOND EMBODIMENT

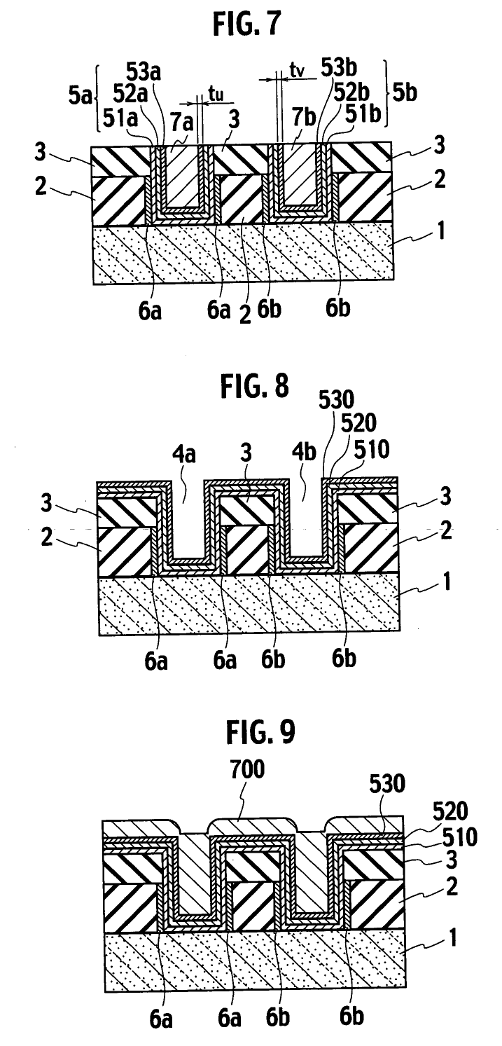

As shown in FIG. 7, a semiconductor device according to the second embodiment of the present invention is different from the first embodiment in that the barrier layers 5a, 5b further include a third barrier films 53a, 53b provided on a surface of the second barrier films 52a, 52b.

The third barrier films 53a, 53b are conductive films having lower film density than the second barrier films 52a, 52b . The third barrier films 53a, 53b have microscopic asperities on surfaces thereof. A film thickness tᵤ, tᵥ of the third barrier film 53a, 53b in contact with the sidewalls of the second barrier films 52a, 52b may be in a range of from about 1 nm to about 3 nm. The third barrier films 53a, 53b can be made from Ti, Nb, Ta, Ru, W, and compounds such as alloys, nitrides, oxides, and carbides, which are made from at least two materials selected from above materials. Other elements of the second embodiment are substantially the same as those of the semiconductor device as shown in FIG. 1, and various explanations are omitted.

With the semiconductor device as shown in FIG. 7, the third barrier films 53a, 53b having a lower film density than the second barrier films 52a, 52b may be provided on the surface of the second barrier films 52a, 52b . The surfaces of the second barrier films 52a, 52b may be flat and have weak adhesion strength. However, the third barrier films 53a, 53b have microscopic asperities on surfaces thereof. Therefore, wetting characteristic between the third barrier films 53a, 53b and the conductors 7a, 7b will be improved. Accordingly, peeling between the barrier layers 5a, 5b and the conductors 7a, 7b is suppressed and thus, reliability is increased.

Next, a description will be given of a method of fabricating the semiconductor device according to the second embodiment with reference to FIGS. 8 and 9. Processes up to deposition of the third barrier films 53a, 32b on the surface of the second barrier films 52a, 52b are substantially the same as in FIGS. 2 to 5.

Referring to FIG. 8, a third barrier 530 is deposited on the surface of the second barrier 520 by sputtering.

The film thickness tᵤ, tᵥ of the third barrier 530 in contact with the sidewall of the second barrier 520 may be controlled within a range of from about 1 nm to about 3 nm. For example, the temperature may be set at 300° C. or lower, and compounds such as alloys, nitrides, oxides, and carbides, which are made from at least two materials selected from Ti, Nb, Ta, Ru, and W may be deposited by sputtering or the like.

Referring to FIG. 9, the conductive layer 700 is deposited on a surface of the third barrier 530 by plating, or the like. The conductive layer 700 is planarized by CMP until the surface of the stopper film 3 is exposed, thus the semiconductor device as shown in FIG. 7 is formed.

With the method of fabricating the semiconductor device according to the second embodiment, since the third barrier films 53a, 53b having asperities on surfaces are deposited after the second barrier films 52a, 52b are deposited, adhesion strength between the barrier layers 5a, 5b and the conductor 7a, 7b will be improved. Therefore, reliability of the semiconductor device will be improved.

### OTHER EMBODIMENTS

Various modifications will become possible for those skilled in the art after receiving the teachings of the present disclosure without departing from the scope thereof.

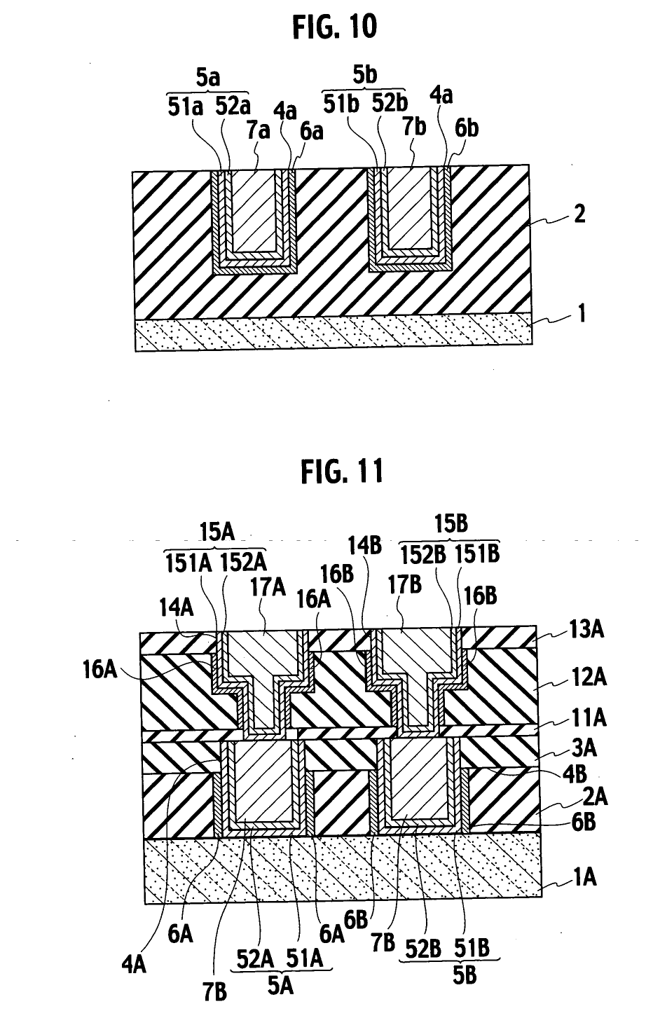

The semiconductor device as described above can be used for various other semiconductor devices. For example, as shown in FIG. 10, the trenches 4a, 4b can be formed only in a region of an upper surface of the porous low k dielectric 2. The metal diffused regions 6a, 6b may be formed along with the interface of the trenches 4a, 4b and the porous low k dielectric 2.

As shown in FIG. 11, the structures as described in the first and second embodiment can be applied to a semiconductor device having a multi-level interconnect structure. Referring to FIG. 11, the semiconductor device may include a lower porous low k dielectric 2A having trenches 4A and 4B disposed on the semiconductor substrate 1A and a lower stopper film 3A disposed on the lower porous low k dielectric 2A. Barrier layers 5A and 5B are provided on the surface of the trenches 4A and 4B and the stopper film 3A.

The lower barrier layers 5A and 5B include first lower barriers 51A and 51B and second lower barriers 52A and 52B. Lower metal diffused region 6A and 6B are provided between the first lower barriers 51A and 51B and the lower porous low k dielectric 2A. Lower interconnects 7A and 7B are filled in the trenches 4A and 4B in contact with the barrier layers 5A and 5B.

A capping layer llA may be formed on the lower stopper film 3A. An upper porous low k dielectric 12A is formed on the capping layer 11A. An upper stopper film 13A is formed on the upper porous low k dielectric 12A. Upper interconnects 17A and 17B and upper barrier layers 15A and 15B surrounding the upper interconnects 17A and 17B are provided in trenches 14A and 14B in the upper porous low k dielectric 12A and the upper stopper film 13A by use of damascene processes.

The upper barrier layers 15A and 15B include upper lower barriers 151A and 151B and second upper barriers 152A and 152B. Upper metal diffused regions 16A and 16B having a thickness of from about 1 nm to about 3.5 nm are provided in the contact surfaces of the first upper barriers 151A and 151B and the upper porous low k dielectric 12A.

The interconnect structure of the semiconductor devices as described above may be suitable for an LSI memory device such as a logic LSI, DRAM, SRAM, or the like, and multi-level interconnects provided on semiconductor elements such as a diode, IGBT, FET, SIT, BJT, SI, GTO thyristor, or the like. However, the present invention is not limited for use in such semiconductor devices. For example, it is a matter of course that the present invention is applicable to a liquid crystal device, a magnetic recording medium, an optical recording medium, a thin-film magnetic head, and a super-conducting element. For example, the fabricating process of the thin film magnetic head may include a repetition of a CVD process, a photolithography process, an etching process and the like, which are similar to those in fabricating the semiconductor device, though the number of processes is small.

What is claimed is:

1. A semiconductor device comprising:
a semiconductor substrate;
a porous low k dielectric disposed on the semiconductor substrate having a plurality of trenches therein, the porous low k dielectric having an effective dielectric constant of 3.0 or less;
a plurality of barrier layers provided on each surface of the trenches, each of the barrier layers including a plurality of films having different film densities;
a plurality of metal diffused regions provided in the porous low k dielectric and contacting the barrier layers; and
a first conductor embedded in one of the trenches in contact with one of the barrier layer.

2. The semiconductor device of claim 1, further comprising:
a second conductor embedded in another one of the trenches adjoining the trench in which the first conductor is embedded, the second conductor being in contact with another one of the barrier layers, wherein the metal diffused regions have a thickness of 1/20 or less of a minimum space width between first and second conductors.

3. The semiconductor device of claim 1, wherein the metal diffused regions have a thickness of about 1 nm to about 3 nm.

4. The semiconductor device of claim 1, wherein each of the barrier layers is made from materials selected from a group consisting of titanium, niobium, ruthenium, tantalum, tungsten, and compound of titanium, niobium, ruthenium, tantalum, and tungsten.

5. The semiconductor device of claim 1, wherein each of the barrier layers comprises;
a first barrier film provided on the surface of the trench; and
a second barrier film provided on a surface of the first barrier film and having a film density higher than the first barrier film.

6. The semiconductor device of claim 5, wherein each of the barrier layers further comprises:
a third barrier film provided on a surface of the second barrier film and having a film density lower than the second barrier film.

7. The semiconductor device of claim 5, wherein the first barrier film has a film thickness of about 1 nm to about 3 nm.

8. The semiconductor device of claim 5, wherein, the second barrier film has a film thickness of about 1 nm to about 10 nm.

9. A method of fabricating a semiconductor device comprising;
forming a porous low k dielectric having an effective dielectric constant of 3.0 or less on a semiconductor substrate;
providing a plurality of trenches in the porous low k dielectric;
providing a plurality of barrier layers, each one of the barrier layers including a plurality of films having different film densities on surfaces of corresponding one of the trenches;
forming a plurality of metal diffused regions in the porous low k dielectric and in contact with the barrier layers; and
embedding first and second conductors in the trenches in contact with the barrier layer, the second conductor is embedded in one of the trenches adjoining the trench in which the first conductor is embedded.

10. The method of claim 9, wherein the metal diffused regions are formed to have a thickness of 1/20 or less of a minimum space width between the first and second conductors.

11. The method of claim 9, wherein the metal diffused regions are formed to have a film thickness of about 1 nm to about 3 nm.

12. The method of claim 9, wherein each of the barrier layers is made from materials selected from a group consisting of titanium, niobium, ruthenium, tantalum, tungsten, and compound of titanium, niobium, ruthenium, tantalum, and tungsten.

13. The method of claim 9, wherein providing the barrier layers comprises:
providing a plurality of first barrier films on each of the surfaces of the trenches;
providing a plurality of second barrier films on each surface of the first barrier films and having a film density higher than the first barrier films.

14. The method of claim 13, further comprising:
providing a plurality of third barrier films on each surface of the second barrier films and having a film density lower than the second barrier films.

15. The method of claim 13, wherein the first barrier films are deposited by sputtering, and the second barrier films are deposited by one of chemical vapor deposition and atomic layer deposition.

16. The method of claim 13, wherein the first barrier films are formed to have a film thickness of about 1 nm to about 3 nm.

17. The method of claim 13, wherein the second barrier films are formed to have a film thickness of about 1 nm to about 10 nm.
